(19) United States
(12) Patent Application Publication
(10) Pub. No.: US 2010/0279492 A1
(43) Pub. Date: Nov. 4, 2010

(54) Method of Fabricating Upgraded Metallurgical Grade Silicon by External Gettering Procedure

(75) Inventor: Tsun-Neng YANG, Taipei City (TW)

Correspondence Address: Jackson Intellectual Property Group PLLC, 106 Starvale Lane, Shipman, VA, 22971, US

(73) Assignee: ATOMIC ENERGY COUNCIL-INSTITUTE OF NUCLEAR ENERGY RESEARCH, Taoyuan (TW)

(21) Appl. No.: 12/434,639

(22) Filed: May 2, 2009

(51) Int. Cl. H01L 21/322

(52) U.S. Cl. 438/476; 257/E21.318

(57) ABSTRACT

Upgraded metallurgical grade silicon (UMG-Si) is fabricated by a ‘green’ (environmental protected) external gettering procedure. Impurities concentration of the fabricated UMG-Si is reduced for 100 times than its source material. The UMG-Si obtained has a purity ratio reaching 4N to 6N. Thus, substrates made of the UMG-Si can be used in solar cells and related photoelectrical applications.

### FIELD OF THE INVENTION

The present invention relates to fabricating upgraded metallurgical grade silicon (UMG-Si); more particularly, relates to UMG-Si having a purity ratio between 4N and 6N by greatly reducing impurities concentration below a depth of a surface of a UMG-Si substrate.

### DESCRIPTION OF THE RELATED ARTS

Two kinds of methods are used to remove impurities of a semiconductor material. One is internal gettering methods; and the other is external gettering methods. Between them, the internal gettering methods are not fit for solar cells.

There are four external gettering methods:

(a) High temperature diffusion is used to directly diffuse atoms of aluminum, phosphorus, etc into the semiconductor material to form metal oxide for trapping the metal impurities.

(b) Mechanical-, laser- or ion-implantation is used to obtain lattice strain on surface of the semiconductor material for forming sinks of impurities.

(c) A thin film is applied on the semiconductor material. The film is made of polycrystalline silicon, silicon nitride, aluminum oxide or silicon germanium alloy. The thin film and the semiconductor material are heterogeneous and strain is thus formed to obtain sinks of impurities at the interface in between owing to lattice mismatch.

(d) Porous-structural surface is used for sinks of impurities.

Then, a layer having the sinks of impurities is etched off to obtain a high-quality semiconductor material from below a depth of the surface of the original semiconductor material.

However, the above methods are chemical methods producing chemical wastes and thus do not provide environmental protection. In addition, no method is announced for fabricating UMG-Si having a purity ratio greater than 4N.

### SUMMARY OF THE INVENTION

The main purpose of the present invention is to fabricate upgraded metallurgical grade silicon (UMG-Si) having a purity ratio between 4N and 6N by greatly reducing impurities concentration below a depth of a surface of a UMG-Si substrate.

To achieve the above purpose, the present invention is a method of fabricating upgraded metallurgical grade silicon by an external gettering procedure, comprising the steps of:

(a) selecting a UMG-Si substrate having a purity ratio between 4N and 6N;

(b) applying a hydrogen-riched amorphous silicon (a-Si:H) film on a surface of the UMG-Si substrate through chemical vapor deposition or physical vapor deposition;

(c) thermal-annealing the UMG-Si substrate to diffuse and gather metal impurities from the UMG-Si substrate to sinks of the a-Si:H film to obtain a high metal-impurities concentration area; and

(d) thermal-etching the a-Si:H film at a high temperature to fully etch out the local high metal-impurities concentration area to obtain a high quality silicon thin layer below a depth of a surface of the UMG-Si substrate. Accordingly, a novel method of fabricating upgraded metallurgical grade silicon by an external gettering procedure is obtained.

### BRIEF DESCRIPTION OF THE DRAWINGS

The present invention will be better understood from the following detailed description of the preferred embodiment according to the present invention, taken in conjunction with the accompanying drawings, in which

FIG. 1 is the flow view showing the preferred embodiment according to the present invention; and

FIG. 2 until FIG. 5 are the structural views showing the preferred embodiment.

### DESCRIPTION OF THE PREFERRED EMBODIMENT

The following description of the preferred embodiment is provided to understand the features and the structures of the present invention.

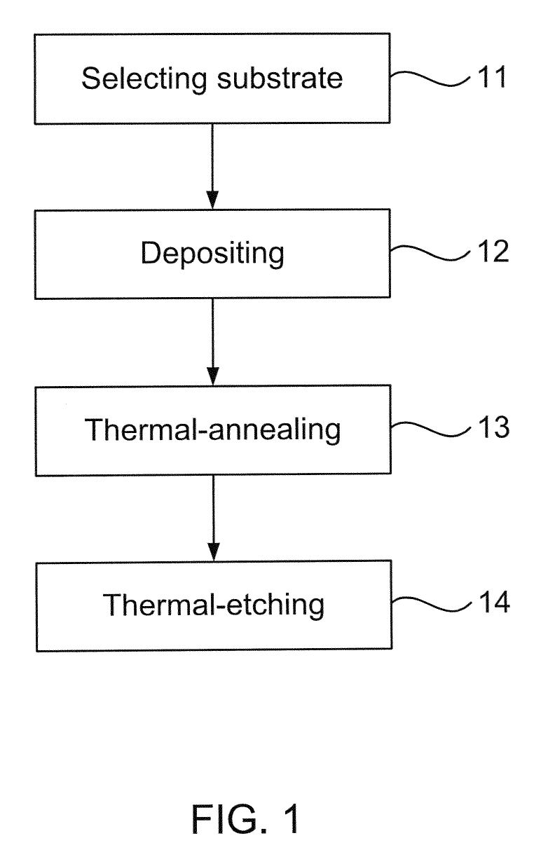

Please refer to FIG. 1 until FIG. 5, which are a flow view and structural views showing the preferred embodiment according to the present invention. As shown in the figures, the present invention is a method of fabricating upgraded metallurgical grade silicon (UMG-Si) by an external gettering procedure, comprising the following steps:

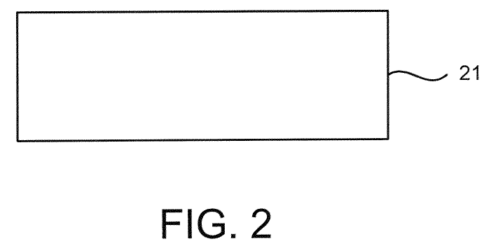

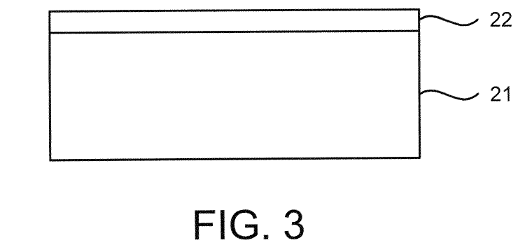

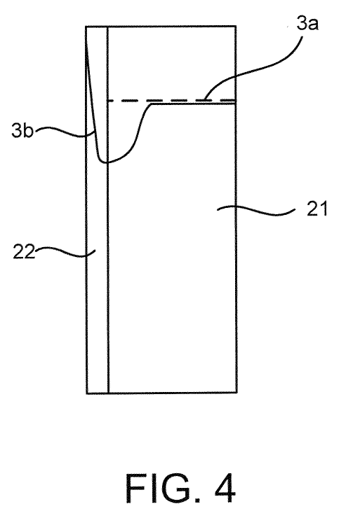

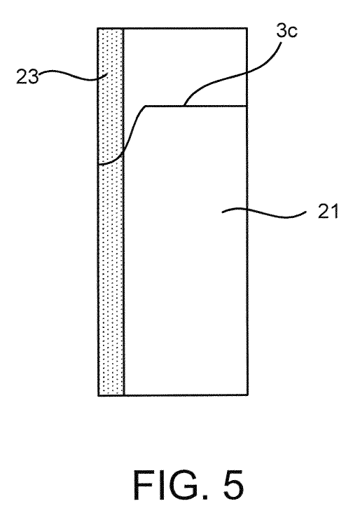

(a) Selecting substrate 11: In FIG. 2, a silicon substrate is selected, where the silicon substrate is a UMG-Si substrate 21 having a purity ratio greater than 4N.

(b) Depositing 12: In FIG. 3, a hydrogen-riched amorphous silicon (a-Si:H) film 22 is applied on a surface of the UMG-Si substrate 21 through physical vapor deposition (PVD) or chemical vapor deposition (CVD).

(c) Thermal-annealing 13: In FIG. 4, the UMG-Si substrate 21 applied with the a-Si:H film 22 is processed through thermal-annealing at a temperature between 1100 and 1300 Celsius degrees (° C.) for a period between 1 and 30 minutes (min). Thus, metal impurities below a depth of the surface of the UMG-Si substrate 21 are diffused and gathered to sinks of the a-Si:H film 22 to obtain a local high metal-impurities concentration area.

(d) Thermal-etching 14: in FIG. 5, the a-Si:H film 22 is processed through thermal-etching with a gas of HCl at a temperature between 1100° C. and 1300° C. for a period between 1 min and 30 min to fully etch off the local high metal-impurities concentration area for obtaining a high quality silicon thin layer 23 from below the depth of the surface of the UMG-Si substrate 21.

On using the present invention, a UMG-Si substrate 21 having a purity ratio greater than 4N is selected. Plasma-enhanced chemical vapor deposition (PECVD) is used to deposit an a-Si:H film 22 on a surface of the UMG-Si substrate 21, where the a-Si:H film 22 has a thickness between 500 Å and 2000 Å. Then, thermal-annealing is processed to expel hydrogen from the a-Si:H film 22 through evaporation to leave sinks in the a-Si:H film 22, where each sink has a shape of a point, line or area. At the same time, metal impurities below a depth of the surface of the UMG-Si substrate 21 are rapidly diffused to the a-Si:H film 22 and are firmly trapped by the sinks in the a-Si:H film 22. Finally, the metal impurities are gathered in the a-Si:H film 22 to form a high metal-impurities concentration area.

In FIG. 3, a first distribution curve of impurities concentration before thermal treatment 3a and a second distribution curve of impurities concentration after thermal treatment 3b show that thermal-annealing process accelerates impurities below a surface of the UMG-Si substrate 21 to diffuse and gather in sinks. Thus, impurities concentration below a depth of the surface of the UMG-Si substrate 21 is reduced by 100 times to form a high-quality silicon thin layer. HCl gas is used for thermal-etching. Under a high temperature, the a-Si:H film 22 having the high impurities concentration area is totally etched off by the HCl gas to obtain a high quality silicon thin layer 23 from below the depth of the surface of the UMG-Si substrate 21 as shown in a third distribution curve of impurities concentration 3c.

After the above processes, the impurities concentration under the depth of the surface of the UMG-Si substrate 21 is reduced by 100 times the original impurities concentration. Hence, the high quality silicon thin layer 23 thus obtained can be applied to solar cells and related photoelectrical applications. Besides, no chemical solvent is used and thickness of the UMG-Si substrate is not affected; and the present invention is a green procedure for the HCl used is recyclable.

To sum up, the present invention is a method of fabricating upgraded metallurgical grade silicon by an external gettering procedure, where impurities concentration below a depth of a surface of a UMG-Si substrate is reduced for 100 times than original impurities concentration; and the present invention is a green procedure while the impurities concentration below the depth of the surface of the UMG-Si substrate is reduced by an external gettering method to obtain a high quality silicon thin layer for solar cells and related photoelectrical applications.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

1. A method of fabricating upgraded metallurgical grade silicon by an external gettering procedure, comprising the steps of:
(a) selecting a silicon substrate having a purity ratio greater than 4N;
(b) applying a hydrogen-riched amorphous silicon (a-Si:H) film on a surface of said silicon substrate through vapor deposition;
(c) thermal-annealing said silicon substrate to diffuse and gather metal impurities below a depth of said surface of said silicon substrate to sinks of said a-Si:H film to obtain a high metal-impurities concentration area; and
(d) thermal-etching said a-Si:H film at a high temperature to fully etch off said local high metal-impurities concentration area to obtain a high quality silicon thin layer from below said depth of said surface of said silicon substrate, wherein said vapor deposition is selected from a group consisting of chemical vapor deposition and physical vapor deposition.

2. The method according to claim 1, wherein said chemical vapor deposition is plasma-enhanced chemical vapor deposition (PECVD).

3. (canceled)

4. The method according to claim 1, wherein, in step (c), said a-Si:H film has a thickness between 500 and 2000 angstroms (Å).

5. The method according to claim 1, wherein, in step (c), said thermal-annealing is processed at a temperature between 1100 and 1300 Celsius degrees (° C.).

6. The method according to claim 1, wherein, in step (c), said thermal-annealing is processed for a period between 1 and 30 minutes (min).

7. The method according to claim 1, wherein, in step (c), said thermal-annealing expels hydrogen from said a-Si:H film through evaporation to leave sinks in said a-Si:H film; and wherein said sink has a shape selected from a group consisting of point, line and area.

8. The method according to claim 1, wherein, in step (c), on obtaining said impurities concentration area, an impurities concentration below said depth of said surface of said silicon substrate is reduced to obtain said high quality silicon thin layer.

9. The method according to claim 1, wherein, in step (d), said thermal-etching is processed at a temperature between 1100° C. and 1300° C.

10. The method according to claim 1, wherein, in step (d), said thermal-etching is processed for a period between 1 min and 30 min.
